(19) United States
(12) Patent Application Publication
(10) Pub. No.: US 2025/0192096 A1
(43) Pub. Date: Jun. 12, 2025

(54) SELF-ASSEMBLY METHOD AND EQUIPMENT

(71) Applicant: Intel Corporation, Santa Clara, CA (US)

(72) Inventors: Yi SHI, Chandler, AZ (US); Thomas SOUNART, Chandler, AZ (US); Michael BAKER, Gilbert, AZ (US); Seyed Hadi ZANDAVI, Phoenix, AZ (US); Feras EID, Chandler, AZ (US); Adel A. ELSHERBINI, Chandler, AZ (US)

(21) Appl. No.: 18/534,850

(22) Filed: Dec. 11, 2023

(51) Int. Cl. H01L 23/00

(52) U.S. Cl. CPC H01L 24/74; H01L 24/80; H01L 2224/74; H01L 2224/80085; H01L 2224/80895; H01L 2224/80896; H01L 2224/80912; H01L 2924/40

(57) ABSTRACT

A system that includes a self-assembly module and a bonding module. The self-assembly module has a liquid dispensing unit, with an applicator and a reservoir for a liquid, that dispenses the liquid onto a wafer, a wafer support, an environmental control unit, a die and wafer transport mechanism, and a processor. A method for performing the hybrid bonding includes providing a wafer, patterning the wafer to form a hydrophobic surface with a plurality of hydrophilic regions, disposing the wafer on the wafer support in the self-assembly module of the hybrid bonding system, dispensing the liquid simultaneously or in batches on the plurality of hydrophilic regions on the wafer, positioning dies on the plurality of hydrophilic regions on the wafer, controlling the humidity and bonding the dies to the wafer using a hybrid bonding process.

### BACKGROUND

For integrated circuit design and fabrication, the need to improve performance and lower costs are constant challenges. The semiconductor industry is presently looking to enhance the performance of semiconductor devices through scaling system-level interconnections, and hybrid bonding may provide a promising solution with the ability to integrate several dies with small interconnection pitches.

Hybrid bonding is a permanent bond that combines a dielectric bond (e.g., SiOx) with embedded metal (e.g., Cu) to form interconnections and provides superior interconnect density, enabling 3D-like packages and advanced memory cubes. Specifically, hybrid bonding provides a solution for interconnects with 10 μm pitches and below by completely avoiding the use of solder bumps, and will instead connect the dies in packages using small copper-to-copper connections.

In die-to-wafer (D2 W) hybrid bonding, obtaining 200 nm alignment accuracy or lower is typically necessary for a high level of electrical performance, and achieving this degree of accuracy at a high enough throughput is challenging with current hybrid bonding equipment since the throughput is dominated by the time required to perform a precision alignment.

One approach to addressing the alignment issue uses a “self-assembly” method, in which the wafers and dies are patterned to create hydrophobic regions surrounding hydrophilic bonding sites, with water droplets being dispensed on the bonding sites on the wafer and confined by the surrounding hydrophobic region. Thereafter, the dies may be placed on the bonding sites. However, it is presently not possible to pick and place multiple dies simultaneously onto a wafer, since the standard water dispense method uses a single nozzle to dispense a specific volume of water onto each bond site immediately before the die placement in a step-by-step process. This step-by-step process ensures that there is a sufficient volume of water on each bonding site and the self-assembly may be performed in an ambient environment without the need for humidity controls. A fast rate of evaporation in a low-humidity environment may limit the self-assembly to process to a sequential (one-by-one) die placement, which can significantly reduce the throughput and this is not desirable.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a present hybrid bonding system according to an aspect of the present disclosure;

FIG. 2 shows an exemplary representation of a patterned wafer with a hydrophobic surface and a plurality of hydrophilic regions according to an aspect of the present disclosure;

FIG. 3 shows an exemplary representation of a liquid dispensing unit according to an aspect of the present disclosure;

FIG. 4 shows an exemplary representation of another liquid dispensing unit according to another aspect of the present disclosure;

FIG. 5 shows an exemplary representation of a liquid being removed from hydrophobic regions of a wafer according to an aspect of the present disclosure;

FIGS. 6A and 6B show an exemplary representation of batch dispensing of a liquid according to an aspect of the present disclosure;

FIGS. 7A and 7B show another exemplary representation of batch dispensing of a liquid according to another aspect of the present disclosure;

FIG. 8 shows yet another exemplary representation of batch dispensing of a liquid according to yet another aspect of the present disclosure;

FIG. 9 shows an exemplary representation of a wafer with a liquid according to an aspect of the present disclosure;

FIGS. 10A through 10J, 10E′, and 10J′ show an exemplary representation of a hybrid bonding process using a present self-assembly module and method according to an aspect of the present disclosure; and

FIG. 11 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, an improved self-assembly tool may provide for the placement and alignment of multiple dies simultaneously. In an aspect, the present self-assembly tool may provide a closed, controlled environment, e.g., using a processing chamber, whereby the self-assembly and bonding processes may be performed at a constant humidity, temperature, and airflow.

In another aspect, the present self-assembly tool may provide wafer-scale liquid dispensing that allows all bonding sites/locations on a wafer to be provided with water at the same or nearly the same time. This simultaneous dispensing of water will increase throughput over the present sequential bonding site by bonding site process. Alternatively, a “collective” or batch water dispense system may be provided in the present self-assembly tool to permit a precise dispensing of a controlled amount of water at each bonding site when different volumes are needed for the individual bonding sites.

The present disclosure provides a self-assembly module including a liquid dispensing unit having an applicator and a reservoir for a liquid, whereby the applicator dispenses the liquid simultaneously onto multiple bonding sites on a wafer, an environmental control unit, a wafer support, and a computer/processor. In an aspect, the self-assembly module further includes a die and wafer transport mechanism.

The present disclosure is also directed to a method that includes providing a wafer, patterning the wafer to form a hydrophobic surface with a plurality of hydrophilic regions, disposing the wafer on a wafer support in a self-assembly module of a hybrid bonding system, dispensing a liquid simultaneously onto multiple bonding sites on the wafer, positioning dies on the plurality of hydrophilic regions on the wafer, and bonding the dies to the wafer using hybrid bonding method.

The present disclosure is further directed to a hybrid bonding system including a self-assembly module having a liquid dispensing unit provided with an applicator and a reservoir for a liquid, whereby the liquid is simultaneously dispensed onto multiple bonding sites on a wafer, a wafer support, an environmental control unit, and a die and wafer transport mechanism. The hybrid bonding system may further include a bonding module and other modules self-assembly tool may provide.

The technical advantages of the present disclosure include, but are not limited to:
(i) providing a self-alignment tool/module for a hybrid bonding system that dispenses a liquid, e.g., water, simultaneously onto multiple bonding sites on a wafer to increase throughput;
(ii) providing environmental controls for humidity and evaporation rate that may permit the amount of liquid at the bonding sites on the wafer to be adjusted and/or maintained, which may improve the alignment and bonding between a die and wafer; and
(iii) providing cost reductions from the increased throughput and improved alignment and bonding results.

To more readily understand and put into practical effect the present self-alignment tool/module and methods, which may provide an improved hybrid bonding system, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

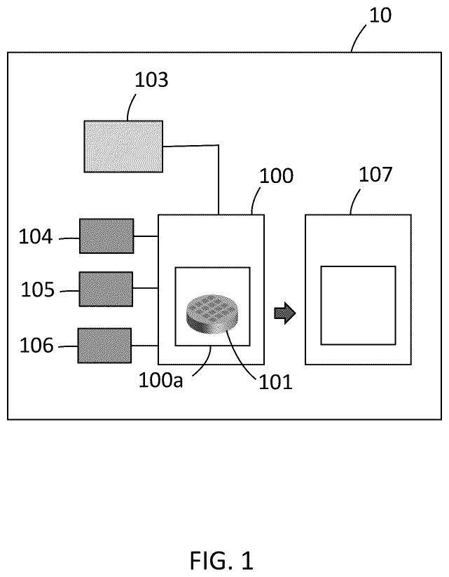

FIG. 1 shows an exemplary representation of a present hybrid bonding system 10 according to an aspect of the present disclosure. The hybrid bonding system 10 includes a self-assembly tool/module 100 and a bonding module 107, which modules may be standalone units or integrated into a single tool, e.g., a cluster tool. The hybrid bonding system 10 may include additional modules, such as cleaning, dicing, plasma activation, and other modules (not shown).

In an aspect, the self-assembly tool/module 100 may include a liquid dispensing unit 104, an environmental control unit 105, and a die/wafer transport mechanism 106. In addition, the self-assembly tool/module 100 and self-alignment process may require a computer/processor 103, which may be integrated with the self-assembly module 100 or associated with the hybrid bonding system 10.

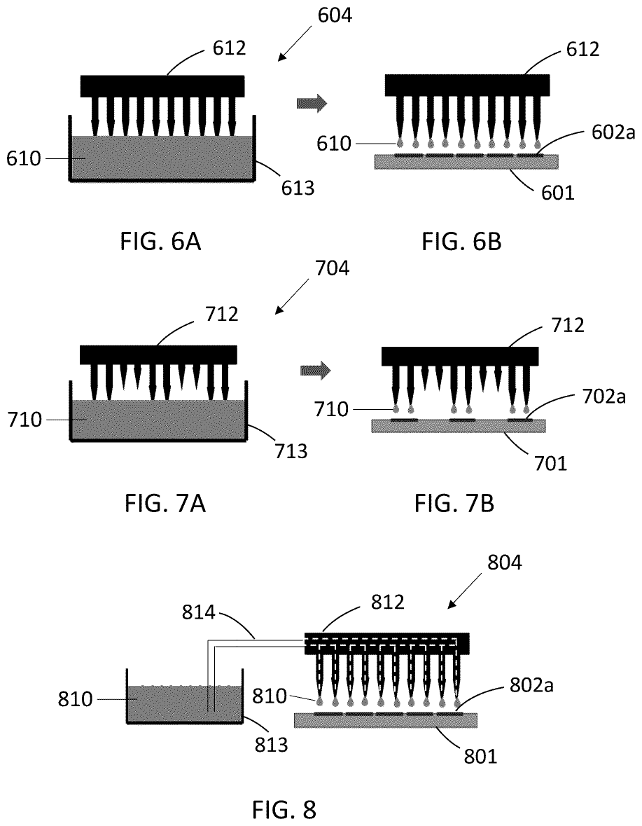

In an aspect, the liquid dispensing unit 104 may include a liquid applicator and a reservoir for a liquid (shown below in FIG. 6), whereby the applicator dispenses the liquid simultaneously onto multiple bonding sites on a wafer. The liquid used with the self-assembly module 100 may typically be water or another aqueous solution.

In another aspect, the environmental control unit 105 may monitor and control the humidity and temperature in the self-assembly module 100, which may include humidity and temperature sensors, an airflow system with fans and vents to provide or shutoff airflow, and heaters for controlling humidity and evaporation. The evaporation rate of the dispensed water may be especially important for smaller dies, which require small amounts of water (e.g., in the range of approximately 0.1 to 0.5 uL), since a high evaporation rate may reduce the time window for die placement. The evaporation rate of the dispensed water may be regulated by the environmental control unit 105, which will control the humidity, airflow, and temperature levels in the self-assembly module 100. By controlling the evaporation rate, the water volume may be adjusted to a precise amount before die placement.

It should be understood that conventional environmental control equipment may be adapted for use with the present self-assembly tool. For example, a present environmental control unit may include an airflow system having an integrated pump and desiccant reservoir that can generate a dry airflow using ambient air, as well as a heated water reservoir to generate necessary humidity within a self-assembly tool and hybrid bonding system. In addition, the temperature control within a present self-assembly tool (e.g., adding a heating element to the wafer support or chuck) may be used to remove excess water, reduce dispensed water volume at a bonding site, or speed up post-placement evaporation at a bonding site, which may be necessary before moving the wafer with assembled dies for annealing.

In yet another aspect, the die/wafer transport mechanism 106 may include robotic arms, clamps, and holders for wafers and dies for the pickup and placement of wafers and dies. For example, in the collective self-assembly process, the dies may be placed on a carrier substrate and transferred all together or in batches onto a patterned wafer.

In an aspect, as shown in FIG. 1, the self-assembly module 100 may have a pre-processed wafer 101, which is positioned on a wafer support (shown below), that is disposed in a housing or chamber 100a for performing a liquid dispensing process for a hybrid bond process. The pre-processed wafer 101 may be patterned to create hydrophobic regions around the hydrophilic regions, i.e., bonding sites, and a die (not shown) may similarly be provided with a hydrophilic region. In addition, according to the present disclosure, the chamber 100a may be used to provide a closed and controlled environment with adjustable or constant humidity, temperature, and airflow by using the present environmental control unit 105.

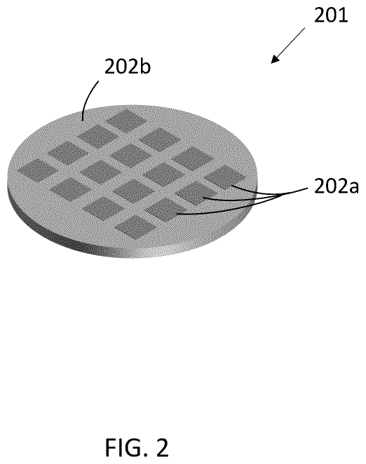

FIG. 2 shows an exemplary representation of a patterned wafer 201 having a hydrophobic surface 202b with a plurality of hydrophilic regions 202a or bonding site 202a according to an aspect of the present disclosure. In an aspect, the wafer 201 will be cleaned for use in the present hybrid bonding process. For example, to make a surface hydrophilic, the surface may be plasma activated, wet cleaned with chemicals, or coated with hydrophilic materials.

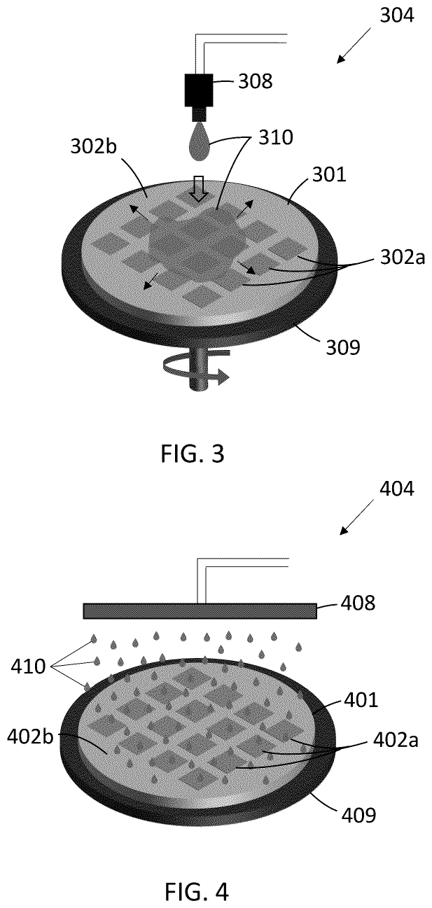

FIG. 3 shows an exemplary representation of a liquid dispensing unit 304 according to an aspect of the present disclosure. In this aspect, the liquid dispensing unit 304 may include a nozzle 308 connected to a water source that delivers water 310 to a wafer 301. The wafer 301 may be placed on a wafer support 309, which may be a turntable platform 309. The wafer 301 may be patterned to create a hydrophobic region 302b around hydrophilic regions 302a, i.e., bonding sites.

In an operation similar to spin coating, a pre-determined volume of water 310 may be placed onto the middle region of the wafer 301, and then the wafer 301 may be spun at appropriate speeds to allow the water 310 to spread out radially across the entire wafer 301, i.e., a simultaneous dispensing of a liquid on multiple bonding sites, and remain only in the hydrophilic regions 302a. The spinning speed should be sufficiently fast to remove any excess water from the hydrophobic region 302b. The volume of the water 310 needed for this process may be determined by the number and sizes of the dies to be bonded, which, in turn, will determine the speed of the turntable platform 309 for removing the water 310 from the hydrophobic region 302b.

FIG. 4 shows an exemplary representation of another liquid dispensing unit 404 according to another aspect of the present disclosure. In this aspect, the liquid dispensing unit 404 may include at least one spray nozzle or mister 408 connected to a water source that delivers water 410 to a wafer 401. The wafer 401 may be patterned to create a hydrophobic region 402b surrounding hydrophilic regions 402a, i.e., bonding sites. The wafer 401 may be placed on a wafer support 409. This aspect uses the mister 408 to spray a fine mist onto the entire wafer 401. In another aspect, the mister 408 may be movable and may sweep over the wafer 401.

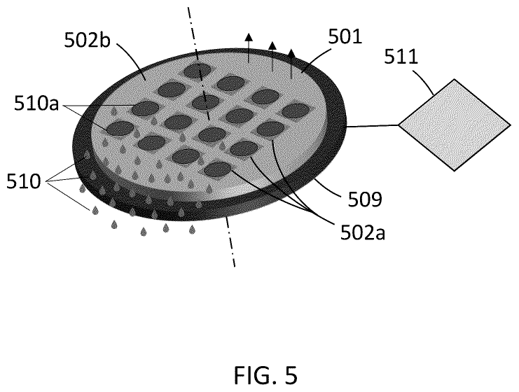

FIG. 5 shows an exemplary representation of a liquid 510 (i.e., water) being removed from a hydrophobic region 502b of a wafer 501 according to an aspect of the present disclosure. In this aspect, the wafer 501 may be placed on a wafer support 509, which may be provided with a tilting mechanism 511. The wafer 501 may be patterned to create a hydrophobic region 502b surrounding hydrophilic regions 502a, i.e., bonding sites, and have dispensed water 510a, which is adhered to the hydrophilic regions 502a. The wafer 501 may be slowly tilted to remove excess water 510b from the hydrophobic regions 502b.

In an aspect, the tilting mechanism 511 may include, for example, configuring the wafer support 509 to tilt on attached axial pins (not shown), having the wafer 501 be positioned in a holder/clamping device that is tiltable, or having extendable vertical pins in the wafer support 509 that lift up one side of the wafer 501. The tilting of the wafer 501 may be effected by a motor and/or a piezoelectric device. The use of a wafer tilting method to remove excess liquid may be performed alone or in combination with other methods, including the spinning method discussed above.

According to the present disclosure, it may be necessary to provide a precise water volume on each bonding site/location, which may not be easy to accomplish with the aforementioned wafer-scale water dispensing methods or other similar methods. For heterogeneous integration, for example, each bonding site/location on a target wafer can have a very different area due to different die sizes. Therefore, a collective or batch liquid dispense system may be needed to provide precise and controlled amounts of water at such bonding sites/locations.

FIGS. 6A and 6B show an exemplary representation of batch dispensing of a liquid (e.g., water) according to an aspect of the present disclosure. In this aspect, as shown in FIG. 6A, a liquid dispensing unit 604 may include a pin array 612 that may be used to transfer a pre-calculated amount of water 610 by a dipping method that is performed by lowering pins 612a of the pin array 612 into a reservoir 613. As shown in FIG. 6B, the water 610 will adhere to the pins 612a and form droplets 610a that may be collectively transferred in a precise amount to hydrophilic bonding sites 602a on a wafer 601. The precise amount of water that is transferred may be controlled by the size and shape of the pin 612a and the depth to which the pin 612a is lowered in the reservoir 613, which will determine the volume of droplet 610a.

FIGS. 7A and 7B show another exemplary representation of batch dispensing of a liquid (e.g., water) according to another aspect of the present disclosure. In this aspect, as shown in FIG. 7A, a liquid dispensing unit 704 may include a pin array 712 that permits individual pins 712a to be retracted so that no water will be transferred to regions of a wafer where water is not needed. A pin 712a may be extended and retracted using an actuator (not shown); for example, a piezoelectric device or an electromagnetic device. The extended pins 712a may be used to transfer pre-calculated amounts of water 710 by a dipping method that is performed by lowering the extended pins 712a of the pin array 712 into a reservoir 713. As shown in FIG. 7B, the water 710 will adhere to the pins 712a and form droplets 710a that may be collectively transferred in a precise amount to hydrophilic bonding sites 702a on a wafer 701. The precise amount of water that is transferred may be controlled by the size of the pin 712a and the depth that the extended pin 712a is lowered into the reservoir 713, which will determine the volume of droplet 710a.

FIG. 8 shows yet another exemplary representation of a batch dispensing of liquid (e.g., water) according to yet another aspect of the present disclosure. In this aspect, a liquid dispensing unit 804 may include a micro dropper array 812′ that is connected by a conduit 814 to a reservoir 813. The water 810 may be pumped to the micro dropper array 812′, which may be used to transfer pre-calculated amounts of water 810a by droppers 812a′ to bonding sites 802a on a wafer 801. Although not shown, a micro dropper array may have valves and gauges to regulate the flow of water to the individual droppers.

According to the present disclosure, a pin array and a micro dripper array may be configured and adapted to dispense a liquid so as to accommodate an individual design layout of a wafer. In addition, it is within the scope of the present disclosure to use pins with different sizes and tip shapes in different locations of a pin array and to use droppers with different sizes in different locations of a micro dropper array, so that different water volumes may be transferred to the corresponding locations on a wafer. In another aspect, if a bonding site is large, it may be necessary to use several pins or droppers to transfer the required volume of water onto the large bonding site. The pre-calculated amounts of water may be determined through simulations or pre-production testing.

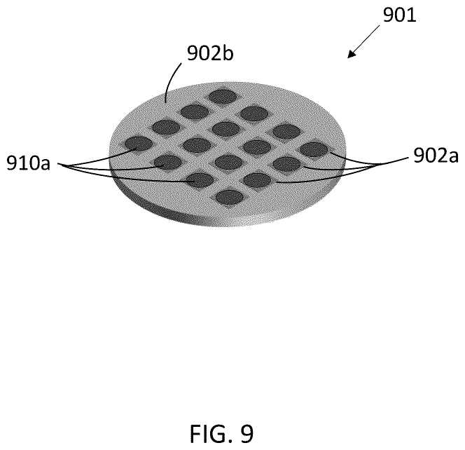

FIG. 9 shows an exemplary representation of a wafer 901 with liquid dispensed thereon according to an aspect of the present disclosure. In this aspect, the wafer 901 is patterned with a hydrophobic region 902b surrounding hydrophilic regions 902a, i.e., bonding sites, and there is dispensed water 910a that is adhering to the hydrophilic regions 902a while the hydrophobic region 902b is water-free. As such, the wafer 901 is ready for the placement of dies in a self-alignment process for hybrid bonding.

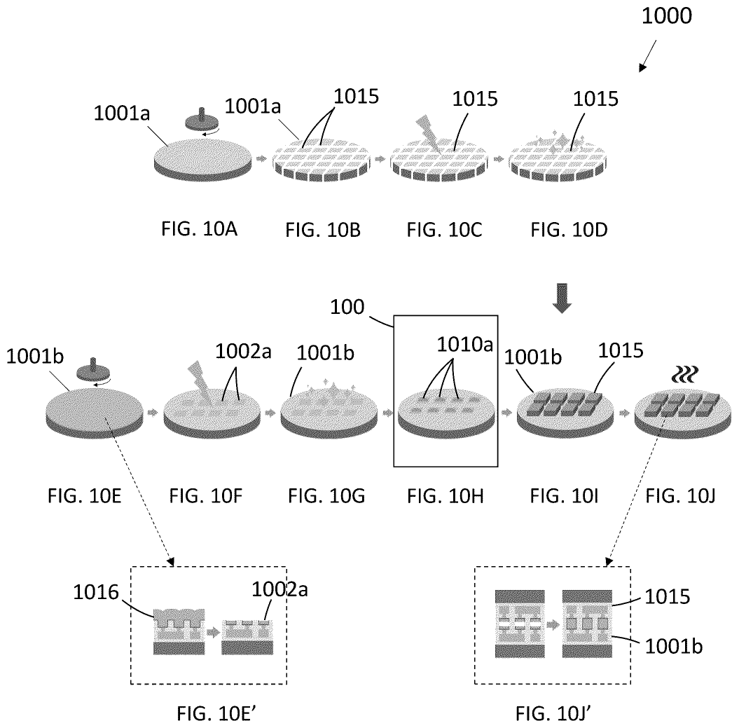

FIGS. 10A through 10J, 10E′, and 10J′ show an exemplary representation of a hybrid bonding process 1000 using a hybrid bonding system with a present self-assembly tool/module according to an aspect of the present disclosure. In this aspect, the hybrid bonding process 1000 may include the steps: 1) a planarization of a wafer 1001a using a chemical mechanical polishing (CMP) step (in FIG. 10A), which is one of the key processes in wafer-level packaging; 2) a separating of dies 1015 of the wafer 1001a using plasma dicing step (in FIG. 10B), which is a chemical process that causes no mechanical damage; 3) a wet chemical or plasma activation step of the dies 1015 (in FIG. 10C), which modifies the surfaces of the dies for bonding; and 4) a cleaning step using an appropriate solution (in FIG. 10D), which prepares the dies 1015 for the self-assembly process.

In addition, the hybrid bonding process 1000 may include the steps: 5) a planarization of a wafer 1001b using a chemical mechanical polishing (CMP) step (in FIG. 10E), which removes a copper layer 1016 from the surface of the wafer 1001b and exposes bonding sites 1002a (in FIG. 10E′); 6) a plasma activation step of the wafer 1001b (in FIG. 10F), which modifies the surface of the wafer 1001b for bonding; 7) a cleaning step using an appropriate solution (in FIG. 10G), which prepares the wafer 1001b for the self-assembly process; 8) a wafer-scale or batch dispensing of water 1010a using the present self-assembly tool 100 (in FIG. 10H), including controlling the humidity and temperature within the self-assembly tool; 9) a transfer of all of the dies 1015 to the wafer 1001b (in FIGS. 101); and 10) an annealing step to complete the hybrid bonding process (in FIG. 10J), which creates a copper to copper bond between the dies 1015 and wafer 1001b (in FIG. 10J′).

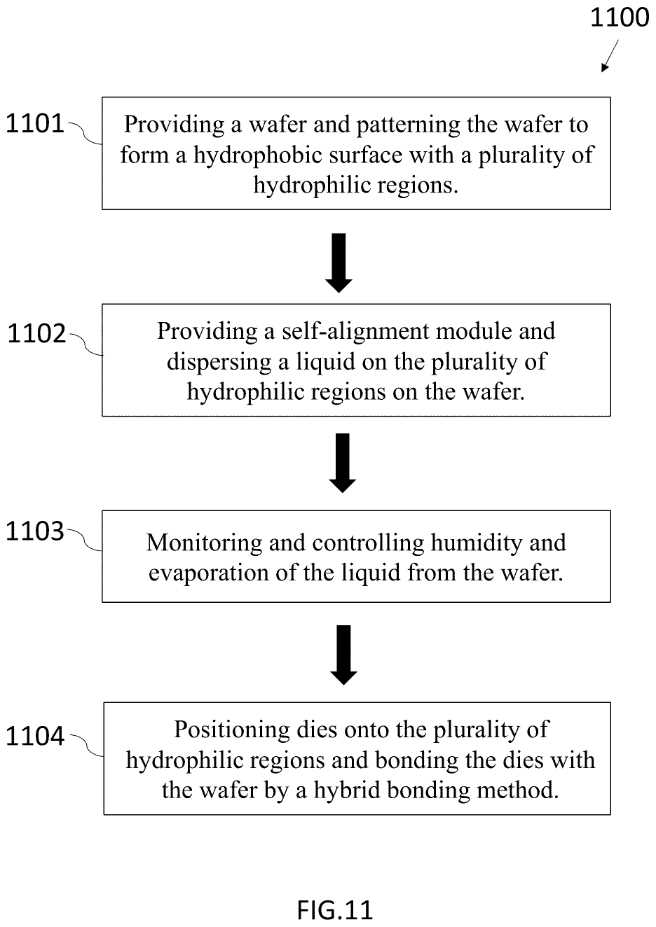

FIG. 11 shows a simplified flow diagram for an exemplary method 1100 according to an aspect of the present disclosure.

The operation 1101 may be directed to providing a wafer and patterning the wafer to form a hydrophobic surface with a plurality of hydrophilic regions.

The operation 1102 may be directed to providing a self-alignment module and dispensing a liquid on the plurality of hydrophilic regions on the wafer.

The operation 1103 may be directed to monitoring and controlling humidity and evaporation of the liquid from the wafer.

The operation 1104 may be directed to positioning dies onto the plurality of hydrophilic regions and bonding the dies with the wafer by a hybrid bonding method.

It will be understood that any property described herein for a particular self-assembly module/tool and method for hybrid bonding may also hold for any self-assembly module/tool using the present features/units described herein. It will also be understood that any property described herein for a specific method may hold for any of the methods described herein. Furthermore, it will be understood that for any self-assembly module/tool and the methods described herein, not necessarily all the components or operations described will be shown in the accompanying drawings or method, but only some (not all) components or operations may be disclosed.

To more readily understand and put into practical effect the self-assembly module/tool having present features and units, they will now be described by way of examples. For the sake of brevity, duplicate descriptions of features and properties may be omitted.

### EXAMPLES

Example 1 provides an apparatus including a processor, a chamber coupled to the processor, a system housed within the chamber, the system including a reservoir for a liquid, an applicator coupled to the reservoir, wherein the applicator is configured to dispense the liquid simultaneously onto multiple locations on a wafer, a humidity sensor, and a wafer support.
Example 2 may include the apparatus of example 1 and/or any other example disclosed herein, further including a die and wafer transport mechanism.
Example 3 may include the apparatus of example 1 and/or any other example disclosed herein, for which the applicator for dispensing the liquid includes at least one nozzle or a mister for dispensing the liquid on an entirety of the wafer.
Example 4 may include the apparatus of example 1 and/or any other example disclosed herein, for which the applicator for dispensing the liquid includes a plurality of transfer pins or a plurality of droppers for dispensing the liquid in batches on designated locations on the wafer.
Example 5 may include the apparatus of example 1 and/or any other example disclosed herein, for which the system further includes an airflow system.
Example 6 may include the apparatus of example 1 and/or any other example disclosed herein, for which the wafer support includes a turntable platform.
Example 7 may include the apparatus of example 1 and/or any other example disclosed herein, for which the wafer support includes a tilting mechanism.
Example 8 provides a method including providing a wafer, patterning the wafer to form a hydrophobic surface with a plurality of hydrophilic regions, for which the hydrophilic regions are bonding sites, disposing the wafer on a wafer support in a self-assembly module of a hybrid bonding system, dispensing a liquid on the plurality of hydrophilic regions on the wafer, positioning dies on the plurality of hydrophilic regions on the wafer, and bonding the dies to the wafer, for which the bonding of the dies is performed using a hybrid bonding method.
Example 9 may include the method of example 8 and/or any other example disclosed herein, for which the dispensing of the liquid is provided simultaneously on the plurality of hydrophilic regions.
Example 10 may include the method of example 9 and/or any other example disclosed herein, for which the simultaneous dispensing of the liquid on the plurality of hydrophilic regions further includes using at least one nozzle or a mister to dispense liquid on an entirety of the wafer.
Example 11 may include the method of example 10 and/or any other example disclosed herein, further including spinning the wafer support to remove liquid that is outside of the plurality of hydrophilic regions.
Example 12 may include the method of example 10 and/or any other example disclosed herein, further including tilting the wafer support to remove liquid that is outside of the plurality of hydrophilic regions.
Example 13 may include the method of example 8 and/or any other example disclosed herein, for which the dispensing of the liquid is provided in batches on the plurality of hydrophilic regions.
Example 14 may include the method of example 13 and/or any other example disclosed herein, for which the batch dispensing of the liquid on the plurality of hydrophilic regions further includes using a plurality of transfer pins or a plurality of droppers.
Example 15 may include the method of example 8 and/or any other example disclosed herein, further including monitoring and controlling humidity and evaporation in the self-assembly module using an environmental control unit.
Example 16 provides a system including a reservoir for storing a liquid, an applicator coupled to the reservoir, for which the applicator is configured to dispense the liquid simultaneously onto multiple locations on a wafer, a wafer support, a humidity sensor, and a wafer transport mechanism.
Example 17 may include the system of example 16 and/or any other example disclosed herein, for which the applicator for dispensing the liquid includes at least one nozzle or a mister for dispensing the liquid on an entirety of the wafer.
Example 18 may include the system of example 16 and/or any other example disclosed herein, for which the applicator for dispensing the liquid includes a plurality of transfer pins or a plurality of droppers for dispensing the liquid in batches onto designated locations on the wafer.
Example 19 may include the system of example 16 and/or any other example disclosed herein, for which the wafer support includes a turntable platform.
Example 20 may include the system of example 16 and/or any other example disclosed herein, for which the wafer support includes a tilting mechanism.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. An apparatus comprising:
a processor;
a chamber coupled to the processor;
a system housed within the chamber, the system comprising:
a reservoir for a liquid;
an applicator coupled to the reservoir, wherein the applicator is configured to dispense the liquid simultaneously onto multiple locations on a wafer;
a humidity sensor; and
a wafer support.

2. The apparatus of claim 1, further comprises a die and wafer transport mechanism.

3. The apparatus of claim 1, wherein the applicator for dispensing the liquid comprises at least one nozzle or a mister for dispensing the liquid on an entirety of the wafer.

4. The apparatus of claim 1, wherein the applicator for dispensing the liquid comprises a plurality of transfer pins or a plurality of droppers for dispensing the liquid in batches on designated locations on the wafer.

5. The apparatus of claim 1, wherein the system further comprises an airflow system.

6. The apparatus of claim 1, wherein the wafer support comprises a turntable platform.

7. The apparatus of claim 1, wherein the wafer support comprises a tilting mechanism.

8. A method comprising:
providing a wafer;
patterning the wafer to form a hydrophobic surface with a plurality of hydrophilic regions, wherein the hydrophilic regions are bonding sites;
disposing the wafer on a wafer support in a self-assembly module of a hybrid bonding system;
dispensing a liquid on the plurality of hydrophilic regions on the wafer;
positioning dies on the plurality of hydrophilic regions on the wafer; and
bonding the dies to the wafer, wherein the bonding of the dies is performed using a hybrid bonding method.

9. The method of claim 8, wherein the dispensing of the liquid is provided simultaneously on the plurality of hydrophilic regions.

10. The method of claim 9, wherein the dispensing of the liquid simultaneously on the plurality of hydrophilic regions further comprises using at least one nozzle or a mister to dispense liquid on an entirety of the wafer.

11. The method of claim 10, further comprises spinning the wafer support to remove liquid that is outside of the plurality of hydrophilic regions.

12. The method of claim 10, further comprises tilting the wafer support to remove liquid that is outside of the plurality of hydrophilic regions.

13. The method of claim 8, wherein the dispensing of the liquid is provided in batches on the plurality of hydrophilic regions.

14. The method of claim 13, wherein the batch dispensing of the liquid on the plurality of hydrophilic regions further comprises using a plurality of transfer pins or a plurality of droppers.

15. The method of claim 8, further comprising monitoring and controlling humidity and evaporation in the self-assembly module using an environmental control unit.

16. A system comprising:
a reservoir for storing a liquid;
an applicator coupled to the reservoir, wherein the applicator is configured to dispense the liquid simultaneously onto multiple locations on a wafer;
a wafer support;
a humidity sensor; and
a wafer transport mechanism.

17. The system of claim 16, wherein the applicator for dispensing the liquid comprises at least one nozzle or mister for dispensing the liquid on an entirety of the wafer.

18. The system of claim 16, wherein the applicator for dispensing the liquid comprises a plurality of transfer pins or a plurality of droppers for dispensing the liquid in batches onto designated locations on the wafer.

19. The system of claim 16, wherein the wafer support comprises a turntable platform.

20. The system of claim 16, wherein the wafer support comprises a tilting mechanism.
